(19) United States
(12) Patent Application Publication
(10) Pub. No.: US 2026/0006749 A1
(43) Pub. Date: Jan. 1, 2026

(54) COOLING DEVICE

(71) Applicant: MITSUBISHI HEAVY INDUSTRIES, LTD., Tokyo (JP)

(72) Inventor: Nobuhide HARA, Tokyo (JP)

(73) Assignee: MITSUBISHI HEAVY INDUSTRIES, LTD., Tokyo (JP)

(21) Appl. No.: 18/992,060

(22) PCT Filed: Feb. 17, 2023
(86) PCT No.: PCT/JP2023/005696

§ 371 Date: Jan. 7, 2025

(30) Foreign Application Priority Data
Jul. 11, 2022 (JP) 2022-111345

(51) Int. Cl. H05K 7/20

(52) U.S. Cl. CPC H05K 7/20345; H05K 7/20136; H05K 7/20327; H05K 7/20409; H05K 7/20809

(57) ABSTRACT

A cooling device includes: a storage tank configured to store a liquid-phase first refrigerant below a heat generating body; a refrigerant supply unit configured to pump up the first refrigerant in the storage tank and supply the first refrigerant to the heat generating body; and a refrigerant cooling unit configured to cool the first refrigerant by supplying a second refrigerant having a lower temperature than the first refrigerant and performing heat exchange between the first refrigerant and the second refrigerant, and the storage tank recovers the first refrigerant supplied to the heat generating body.

### TECHNICAL FIELD

The present disclosure relates to a cooling device.

Priority is claimed on Japanese Patent Application No. 2022-111345, filed Jul. 11, 2022, the content of which is incorporated herein by reference.

### BACKGROUND ART

Patent Document 1 discloses a cooling system that directly cools an electronic device having a heat generating body by immersing the electronic device in a liquid-phase refrigerant. The cooling system includes a cooling tank in which a refrigerant is contained. The electronic device is immersed in a refrigerant of the cooling tank.

### CITATION LIST

### Patent Document

Patent Document 1: PCT International Publication No. WO 2016/075838

### SUMMARY OF INVENTION

### Technical Problem

However, in the cooling system described in Patent Document 1, it is necessary to immerse the entire electronic device in the refrigerant of the cooling tank. Therefore, this cooling system requires a large amount of refrigerant. Since the refrigerant is expensive, it is required to reduce the amount of refrigerant used.

The present disclosure has been made in order to solve the above-described problems, and an object of the present disclosure is to provide a cooling device capable of reducing the amount of refrigerant used.

### Solution to Problem

In order to solve the above-described problem, according to the present disclosure, there is provided a cooling device including: a storage tank configured to store a liquid-phase first refrigerant below a heat generating body; a refrigerant supply unit configured to pump up the first refrigerant in the storage tank and supply the first refrigerant to the heat generating body; and a refrigerant cooling unit configured to cool the first refrigerant by supplying a second refrigerant having a lower temperature than the first refrigerant and performing heat exchange between the first refrigerant and the second refrigerant, in which the storage tank recovers the first refrigerant supplied to the heat generating body.

### Advantageous Effects of Invention

According to the cooling device of the present disclosure, the amount of refrigerant used can be reduced.

### BRIEF DESCRIPTION OF DRAWINGS

FIG. 1 A perspective view showing the configuration of a cooling device according to a first embodiment of the present disclosure.

FIG. 2 A side view showing a configuration of the cooling device according to the first embodiment of the present disclosure.

FIG. 3 A perspective view showing the configuration of a cooling device according to a second embodiment of the present disclosure.

FIG. 4 A cross-sectional view of a cooling tube according to the second embodiment of the present disclosure.

FIG. 5 A side view of fins according to a first modification example of the second embodiment of the present disclosure.

FIG. 6 A perspective view showing the configuration of a cooling device according to a second modification example of the second embodiment of the present disclosure.

### DESCRIPTION OF EMBODIMENTS

### First Embodiment

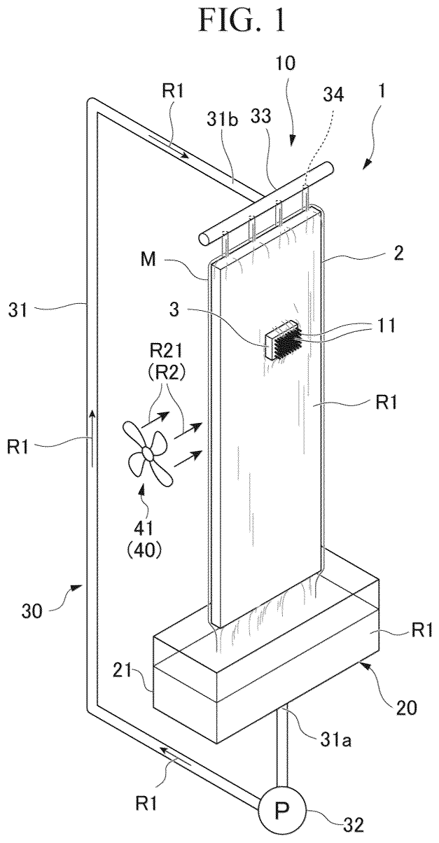

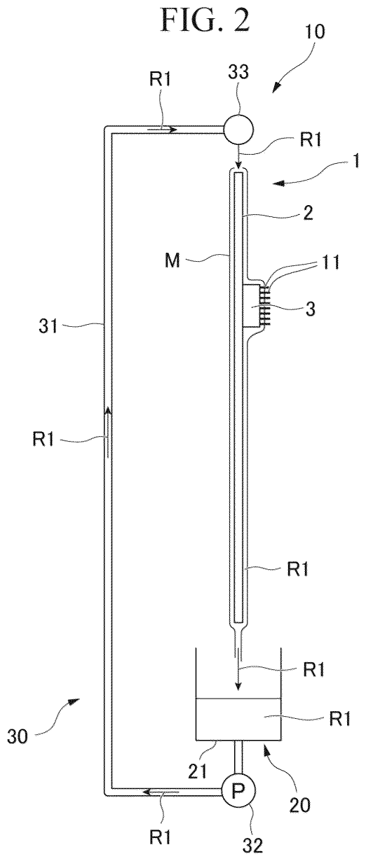

Hereinafter, a cooling device 10 according to a first embodiment of the present disclosure will be described with reference to FIGS. 1 and 2.

The cooling device 10 is used for cooling an electronic device that performs high-speed calculation. As shown in FIG. 1, in the present embodiment, the cooling device 10 is used for a server 1 installed in a data center.

The server 1 has a print substrate provided with elements such as a CPU and a GPU. Since the CPU or the GPU is a component that is responsible for high-speed calculation processing, a high load is applied.

Therefore, the CPU or the GPU generates heat at a higher temperature than other locations of the server 1.

In the following, the print substrate of the server 1 will be simply referred to as a “substrate 2”, and an element that generates heat at a particularly high temperature in the substrate 2, such as a CPU or a GPU, will be referred to as a “heat generating body 3” in some cases.

The substrate 2 is formed in a rectangular plate shape. The heat generating body 3 is provided on a surface of the substrate 2. The substrate 2 is disposed to extend in the up-down direction.

### Configuration of Cooling Device

Next, a configuration of the cooling device 10 will be described.

As shown in FIGS. 1 and 2, the cooling device 10 includes a storage tank 20, a refrigerant supply unit 30, a refrigerant cooling unit 40, and fins 11.

### Storage Tank

The storage tank 20 is disposed below the substrate 2. The storage tank 20 is a box-shaped container having a rectangular parallelepiped shape. The storage tank 20 is open upward. The storage tank 20 stores a liquid-phase first refrigerant R1 below the heat generating body 3. The first refrigerant R1 is a refrigerant having insulating properties. Examples of the first refrigerant R1 include liquids based on fluorocarbons. The first refrigerant R1 is supplied to the heat generating body 3 by the refrigerant supply unit 30 described below. The heat generating body 3 is cooled by performing heat exchange with the first refrigerant R1. The storage tank 20 recovers the first refrigerant R1 supplied to the heat generating body 3.

### Refrigerant Supply Unit

The refrigerant supply unit 30 pumps up the first refrigerant R1 in the storage tank 20 and supplies the first refrigerant R1 to the heat generating body 3. The refrigerant supply unit 30 of the present embodiment causes the first refrigerant R1 to flow downward on the substrate 2 and forms a liquid film M of the first refrigerant R1 in a region including the heat generating body 3 on the substrate 2. The refrigerant supply unit 30 includes a circulation pipe 31, a pump 32, and a header pipe 33.

### Circulation Pipe

The circulation pipe 31 is provided outside the storage tank 20. One end 31a of the circulation pipe 31 is connected to a bottom portion 21 of the storage tank 20. The circulation pipe 31 communicates with the inside of the storage tank 20. The circulation pipe 31 extends upward from the bottom portion 21 of the storage tank 20. The other end 31b of the circulation pipe 31 is positioned above the substrate 2. The first refrigerant R1 flows through the circulation pipe 31.

### Pump

The pump 32 is provided in the circulation pipe 31. In the present embodiment, the pump 32 is provided below the bottom portion 21 of the storage tank 20. The pump 32 pumps the first refrigerant R1 and causes the first refrigerant R1 to flow from one end 31a to the other end 31b of the circulation pipe 31.

### Header Pipe

The header pipe 33 is provided at the other end 31b of the circulation pipe 31. The header pipe 33 communicates with the circulation pipe 31. The header pipe 33 is disposed immediately above the substrate 2. The header pipe 33 is along the upper edge of the substrate 2. A plurality of supply holes 34 are provided in the header pipe 33. The plurality of supply holes 34 are disposed in a row at equal intervals. Each supply hole 34 is open downward. The first refrigerant R1 supplied from the circulation pipe 31 flows through the header pipe 33.

### Refrigerant Cooling Unit

The refrigerant cooling unit 40 cools the first refrigerant R1 by supplying the second refrigerant R2 having a lower temperature than the first refrigerant R1 and performing heat exchange between the first refrigerant R1 and the second refrigerant R2. In the present embodiment, the refrigerant cooling unit 40 supplies the second refrigerant R2 to the liquid film M of the first refrigerant R1 formed on the substrate 2.

In the present embodiment, the refrigerant cooling unit 40 is installed at a position facing the hear generating body 3 on the substrate 2. The location on the substrate 2 where the heat generating body 3 is provided has a higher heat generation density than other locations on the substrate 2. That is, the refrigerant cooling unit 40 supplies the second refrigerant R2 to the region on the substrate 2 where the heat generation density is high.

The refrigerant cooling unit 40 of the present embodiment is a cooling fan 41, and the second refrigerant R2 is air R21. The cooling fan 41 cools the first refrigerant R1 by directly supplying the air R21 to the liquid film M of the first refrigerant R1 formed on the substrate 2. In addition, the cooling fan 41 directly supplies the air R21 to the heat generating body 3 in a targeted manner.

### Fin

The fins 11 are provided in a region on the substrate 2 where the liquid film M of the first refrigerant R1 is formed. A plurality of fins 11 of the present embodiment are provided on the heat generating body 3. The fins 11 are formed in a pin shape extending perpendicularly from the heat generating body 3 to the surface of the substrate 2. The plurality of fins 11 are regularly disposed in the up-down direction and the horizontal direction. The plurality of fins 11 are disposed in a zigzag manner to be alternately arranged in each of the up-down direction and the horizontal direction in a case of being viewed from the normal direction of the surface of the substrate 2.

### Circulation of First Refrigerant

Next, the circulation of the first refrigerant R1 in the cooling device 10 will be described.

First, the first refrigerant R1 stored in the bottom portion 21 of the storage tank 20 flows into the circulation pipe 31. The first refrigerant R1 flowing into the circulation pipe 31 is pumped from one end 31a to the other end 31b of the circulation pipe 31 by the pump 32. Thereafter, the first refrigerant R1 is supplied to the header pipe 33. The first refrigerant R1 flows out from the supply hole 34 of the header pipe 33 downward.

The first refrigerant R1 that has flowed out from the supply hole 34 is supplied to the upper edge of the substrate 2. The first refrigerant R1 flows from the upper edge to the lower edge of the substrate 2 by its own weight. In this case, the liquid film M of the first refrigerant R1 is formed on the substrate 2. The first refrigerant R1 flows in a state of the liquid film M. Therefore, the first refrigerant R1 flows gently on the substrate 2 as compared with the circulation pipe 31 and the header pipe 33. In addition, on the substrate 2, the flow rate of the first refrigerant R1 is constant.

The first refrigerant R1 flowing on the substrate 2 performs heat exchange with the heat generating body 3 and the substrate 2.

As a result, the heat generating body 3 and the substrate 2 are cooled, and the first refrigerant R1 is heated.

The second refrigerant R2 is supplied from the refrigerant cooling unit 40 to the liquid film M of the first refrigerant R1 formed on the substrate 2. The first refrigerant R1 performs heat exchange with the second refrigerant R2. As a result, the first refrigerant R1 is cooled. In the present embodiment, the refrigerant cooling unit 40 is the cooling fan 41, and the cooling fan 41 directly supplies the air R21 to the liquid film M of the first refrigerant R1.

In addition, the air R21 supplied from the cooling fan 41 also performs heat exchange with the heat generating body 3 and the substrate 2. As a result, the heat generating body 3 and the substrate 2 are further cooled.

When the first refrigerant R1 reaches the lower edge of the substrate 2, the first refrigerant R1 flows down from the substrate 2 toward the storage tank 20. The first refrigerant R1 is stored in the liquid-phase storage tank 20. Thereafter, the first refrigerant R1 flows into the circulation pipe 31 again. In this manner, the first refrigerant R1 circulates in the cooling device 10.

### Actions and Effects

With the cooling device 10 according to the present embodiment, the following actions and effects are exhibited.

In the present embodiment, the cooling device 10 includes the storage tank 20, the refrigerant supply unit 30, and the refrigerant cooling unit 40. The storage tank 20 stores a liquid-phase first refrigerant R1 below the heat generating body 3. The refrigerant supply unit 30 pumps up the first refrigerant R1 in the storage tank 20 and supplies the first refrigerant R1 to the heat generating body 3. The refrigerant cooling unit 40 cools the first refrigerant R1 by supplying the second refrigerant R2 having a lower temperature than the first refrigerant R1 and performing heat exchange between the first refrigerant R1 and the second refrigerant R2. Further, the storage tank 20 recovers the first refrigerant R1 supplied to the heat generating body 3.

As a result, the first refrigerant R1 supplied to the heat generating body 3 moves downward due to its own weight and returns to the storage tank 20. The first refrigerant R1 returned to the storage tank 20 is again supplied to the heat generating body 3 by the refrigerant supply unit 30. Therefore, the storage tank 20 may temporarily store the first refrigerant R1 before the first refrigerant R1 is supplied to the heat generating body 3. Therefore, the cooling device 10 does not need to fill the storage tank 20 with the first refrigerant R1 to the extent that the heat generating body 3 can be immersed in the storage tank 20. Therefore, with the cooling device 10 of the present embodiment, the amount of the first refrigerant R1 used can be reduced.

In addition, in the present embodiment, the heat generating body 3 is provided on the substrate 2 that extends in the up-down direction above the storage tank 20. The refrigerant supply unit 30 causes the first refrigerant R1 to flow downward on the substrate 2 to form the liquid film M of the first refrigerant R1 in a region including the heat generating body 3 on the substrate 2.

As a result, the cooling device 10 can cause the first refrigerant R1 to flow at a constant speed. Therefore, the cooling device 10 can suppress the occurrence of stagnant regions of the first refrigerant R1 on the substrate 2. Therefore, the first refrigerant R1 can flow uniformly on the substrate 2. As a result, the cooling device 10 can uniformly cool the entire substrate 2 and the heat generating body 3 installed on the substrate 2.

In addition, in the present embodiment, the refrigerant cooling unit 40 supplies the second refrigerant R2 to the liquid film M of the first refrigerant R1 formed on the substrate 2.

As a result, the refrigerant cooling unit 40 can directly cool the liquid film M of the first refrigerant R1. Therefore, the cooling device 10 can efficiently cool the first refrigerant R1. Therefore, the amount of the first refrigerant R1 used by the cooling device 10 is further reduced.

In the present embodiment, the refrigerant cooling unit 40 supplies the second refrigerant R2 to a region on the substrate 2, such as the heat generating body 3, where the heat generation density is high.

As a result, the cooling device 10 can cool a region having a high heat generation density on the substrate 2 including the heat generating body 3 with both the first refrigerant R1 and the second refrigerant R2. Therefore, the cooling efficiency of the cooling device 10 can be improved.

In addition, in the present embodiment, the cooling device 10 includes the fins 11 in a region on the substrate 2 where the liquid film M of the first refrigerant R1 is formed.

Accordingly, the cooling device 10 can control the thickness of the liquid film M of the first refrigerant R1 by passing the fins 11 through the liquid film M of the first refrigerant R1. For example, the fins 11 are installed in the vicinity of a region on the substrate 2, such as an installation location of the heat generating body 3, where a heat generation density is high, and the thickness of the liquid film M of the first refrigerant R1 can be increased in the region on the substrate 2 where a heat generation density is high. Therefore, the cooling device 10 can intensively cool a region on the substrate 2 where a heat generation density is high. In addition, the contact area between the substrate 2 and the first refrigerant R1 is increased by the fins 11. That is, the heat transfer area between the substrate 2 and the first refrigerant R1 is increased. Therefore, the cooling device 10 can efficiently cool the substrate 2.

In addition, in the first embodiment, a case where the first refrigerant R1 cools in the liquid-phase the heat generating body 3 and the substrate 2 has been described, but the present invention is not limited thereto. For example, a part of the first refrigerant R1 may evaporate on the substrate 2. In this case, the cooling device 10 can cool the region on the substrate 2 including the heat generating body 3 by using the evaporation latent heat in a case where the first refrigerant R1 evaporates.

In addition, in the first embodiment, the fins 11 are formed in a pin shape, but the present invention is not limited thereto. The fins 11 may be formed in a plate shape, a comb shape, or a block shape. In addition, the fins 11 may be formed in a porous shape. Further, the fins 11 may not be provided on the heat generating body 3. For example, the fins 11 may be provided at a location other than the heat generating body 3 on the substrate 2. In addition, a plurality of types of fins 11 having different shapes may be provided on the substrate 2.

In addition, in the first embodiment, the refrigerant cooling unit 40 supplies the air R21 as the second refrigerant R2 to the first refrigerant R1. However, the present invention is not limited thereto. For example, the refrigerant supply unit 30 may supply the second refrigerant R2 other than the air R21 in order to prevent deterioration of the first refrigerant R1.

In addition, in the first embodiment, the refrigerant cooling unit 40 is the cooling fan 41, and the cooling fan 41 directly supplies the air R21 to the first refrigerant R1. However, the present invention is not limited thereto. The refrigerant cooling unit 40 may be disposed in the circulation path of the first refrigerant R1 and may cool the first refrigerant R1 with a refrigerant other than a gas.

In addition, in the first embodiment, the refrigerant supply unit 30 causes the first refrigerant R1 to flow from the upper edge of the substrate 2 and supplies the first refrigerant R1 to the entire substrate 2. However, the present invention is not limited thereto. The refrigerant supply unit 30 may supply the first refrigerant R1 to a part of a location on the substrate 2 to be cooled in a targeted manner. In addition, the refrigerant supply unit 30 may supply the first refrigerant R1 in an impingement manner, or may supply the first refrigerant R1 by spraying in a spray shape.

### Second Embodiment

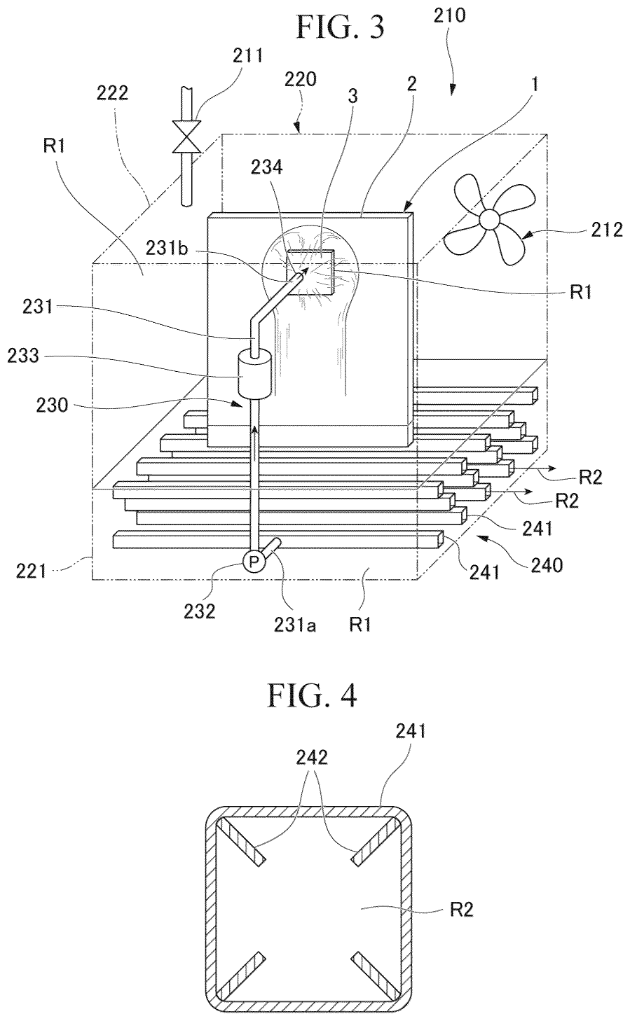

Hereinafter, a cooling device 210 according to a second embodiment of the present disclosure will be described with reference to FIGS. 3 and 4. The same configurations as those in the first embodiment described above will be given the same names and the same reference signs, and the descriptions thereof will be appropriately omitted.

### Cooling Device

As shown in FIG. 3, the cooling device 210 includes a storage rank 220, a relief valve 211, a refrigerant supply unit 230, a refrigerant cooling unit 240, and a fan 212.

### Storage Tank

The storage tank 220 is a box-shaped container having a rectangular parallelepiped shape. Unlike the first embodiment, an upper portion 222 of the storage tank 220 is closed. The storage tank 220 accommodates the entire substrate 2 and the heat generating body 3 therein. In the present embodiment, the substrate 2 is disposed in a vertical posture to extend in the up-down direction, as in the first embodiment. In addition, the storage tank 220 stores the first refrigerant R1 therein in both liquid and gas phases. The liquid-phase first refrigerant R1 is stored in a bottom portion 221 of the storage tank 220. A liquid level of the liquid-phase first refrigerant R1 stored in the storage tank 220 is positioned below the heat generating body 3. The first refrigerant R1 in the gas phase is stored in the upper portion 222 of the storage tank 220.

### Relief Valve

The relief valve 211 is attached to the upper portion 222 of the storage tank 220.

The relief valve 211 communicates with the inside of the storage tank 220. The relief valve 211 is opened in a case where the internal pressure of the storage tank 220 is increased. In a case where the relief valve 211 is opened, the internal pressure of the storage tank 220 is reduced.

### Refrigerant Supply Unit

The refrigerant supply unit 230 is accommodated inside the storage tank 220. The refrigerant supply unit 230 pumps up the first refrigerant R1 stored in the bottom portion 221 of the storage tank 220 and sprays the first refrigerant R1 toward the heat generating body 3. The refrigerant supply unit 230 includes a circulation pipe 231. a pump 232, a filter 233, and a spray unit 234.

### Circulation Pipe

The circulation pipe 231 extends from the bottom portion 221 in the storage tank 220 toward the upper portion 222. One end 231a of the circulation pipe 231 is immersed in the first refrigerant R1 in the liquid phase stored in the storage tank 220. The other end 231b of the circulation pipe 231 is provided at the same position in the up-down direction as the heat generating body 3.

### Pump

The pump 232 is provided in the circulation pipe 231. In the present embodiment, the pump 232 is immersed in the first refrigerant R1 of the liquid phase stored in the storage tank 220. The pump 232 pumps the first refrigerant R1 in the storage tank 220 and causes the first refrigerant R1 to flow from one end 231a to the other end 231b of the circulation pipe 231.

### Filter

The filter 233 is provided in the circulation pipe 231. The filter 233 is provided on the other end 231b side of the circulation pipe 231 with respect to the pump 232. The filter 233 is, for example, an activated carbon filter.

### Spray Unit

The spray unit 234 is provided at the other end 231b of the circulation pipe 231. The first refrigerant R1 is supplied from the circulation pipe 231 to the spray unit 234. The spray unit 234 faces the heat generating body 3. The spray unit 234 sprays the first refrigerant R1 toward the heat generating body 3. The first refrigerant R1 is sprayed in a so-called spray shape to spread radially approaching the heat generating body 3.

### Refrigerant Cooling Unit

The refrigerant cooling unit 240 is provided at the bottom portion 221 of the storage tank 220. The refrigerant cooling unit 240 of the present embodiment is a cooling tube 241 that penetrates the bottom portion 221 of the storage tank 220. A plurality of cooling tubes 241 are provided at intervals in the up-down direction and the horizontal direction. The plurality of cooling tubes 241 extend in parallel to each other in the storage tank 220. In addition, the cooling tube 241 extends in one direction along a horizontal plane and penetrates a pair of opposing side walls of the storage tank 220. The second refrigerant R2 flows through the cooling tube 241. The cooling tube 241 cools the liquid-phase first refrigerant R1 by performing heat exchange between the second refrigerant R2 and the liquid-phase first refrigerant R1 stored in the storage tank 220.

In addition, as shown in FIG. 4, the cooling tube 241 is formed in a quadrangular tubular shape. A plurality of tube fins 242 are provided on an inner peripheral surface of the cooling tube 241. The tube fins 242 are provided at a corner portion of an inner peripheral surface of the cooling tube 241 in a cross-sectional view perpendicular to the extension direction of the cooling tube 241. Each of tube fins 242 is formed to extend linearly toward the center of the cooling tube 241.

### Fan

The fan 212 is provided in the storage tank 220. The fan 212 is disposed in the upper portion 222 in the storage tank 220. The fan 212 is positioned above a liquid level of the liquid-phase first refrigerant R1 stored in the bottom portion 221 of the storage tank 220. The fan 212 circulates the gas-phase first refrigerant R1 in the storage tank 220.

### Circulation of First Refrigerant

Next, the circulation of the first refrigerant R1 in the cooling device 210 will be described.

First, the first refrigerant R1 stored in the bottom portion 221 of the storage tank 220 flows into the circulation pipe 231. The first refrigerant R1 flowing into the circulation pipe 231 is pumped from one end 231a to the other end 231b of the circulation pipe 231 by the pump 232. Thereafter, the first refrigerant R1 is supplied to the spray unit 234. The spray unit 234 sprays the first refrigerant R1 radially toward the heat generating body 3.

The first refrigerant R1 performs heat exchange with the heat generating body 3. As a result, the heat generating body 3 is cooled, and the first refrigerant R1 is heated.

The first refrigerant R1 flows down from the heat generating body 3 toward the storage tank 220. The first refrigerant R1 is recovered in the liquid-phase storage tank 220. The cooling tube 241 cools the first refrigerant R1 by performing heat exchange between the first refrigerant R1 and the second refrigerant R2 recovered in the bottom portion 221 of the storage tank 220. The cooled first refrigerant R1 flows into the circulation pipe 231 again. In this manner, the first refrigerant R1 circulares in the cooling device 210.

In addition, a part of the first refrigerant R1 evaporates while circulating in the cooling device 210. Therefore, the gas-phase first refrigerant R1 is stored in the upper portion 222 of the storage tank 220. The heat content of the gas-phase first refrigerant R1 stored in the storage tank 220 increases as the position is higher.

The fan 212 circulates the first refrigerant R1 in a gas phase inside the storage tank 220. As a result, the gas-phase first refrigerant R1 in the upper portion 222 of the storage tank 220 comes into contact with the liquid-phase first refrigerant R1, and heat exchange is performed between the gas-phase first refrigerant R1 and the liquid-phase first refrigerant R1. As a result, a part of the gas-phase first refrigerant R1 is condensed and is recovered as the liquid-phase first refrigerant R1 in the bottom portion 221 of the storage tank 220. The first refrigerant R1 recovered in the bottom portion 221 of the storage tank 220 flows into the circulation pipe 231 again.

### Actions and Effects

With the cooling device 210 of the present embodiment, the following actions and effects are exhibited.

In the present embodiment, the refrigerant supply unit 230 sprays the first refrigerant R1 toward the heat generating body 3.

As a result, the cooling device 210 can cause the first refrigerant R1 to collide with the heat generating body 3. Therefore, the cooling device 210 can perforin so-called impingement cooling on the heat generating body 3. Therefore, the cooling efficiency of the cooling device 210 can be improved.

In addition, in the present embodiment, the cooling device 210 includes the fan 212 in the storage tank 220. The fan 212 circulates the gas-phase first refrigerant R1 in the storage tank 220.

As a result, the fan 212 can circulate the gas-phase first refrigerant R1 inside the storage tank 220. Therefore, the cooling device 210 can transfer the high-temperature heat accumulated above the storage tank 220 to the liquid-phase first refrigerant R1 stored in the bottom portion 221 of the storage tank 220. As a result, a part of the gas-phase first refrigerant R1 is condensed and is recovered as the liquid-phase first refrigerant R1 in the bottom portion 221 of the storage tank 220. That is, the cooling device 210 can return the first refrigerant R1 that has once evaporated to a liquid phase. Therefore, the cooling efficiency of the cooling device 210 can be further improved.

In addition, in the present embodiment, the cooling tube 241 is formed in a quadrangular tubular shape.

Accordingly, the cooling tube 241 can be installed with high density in the storage tank 220. Therefore, the cooling efficiency of the cooling device 210 can be further improved.

In addition, in the present embodiment, a plurality of tube fins 242 are provided on the inner peripheral surface of the cooling tube 241.

As a result, the contact area between the cooling tube 241 and the second refrigerant R2 is increased. As a result, the heat exchange between the first refrigerant R1 and the second refrigerant R2 is performed more efficiently. Therefore, the cooling efficiency of the cooling device 210 can be further improved. Therefore, for example, even in a case where the second refrigerant R2 flowing in the cooling tube 241 has low heat transfer efficiency like a gas, the cooling device 210 can sufficiently cool the first refrigerant R1.

In addition, in the second embodiment, the tube fins 242 inside the cooling tube 241 extend linearly toward the center portion of the cooling tube 241, but the present invention is not limited thereto. The shape of the tube fin 242, such as the thickness or the length of the tube fin 242, can be appropriately changed. The tube fins 242 may extend while being curved toward the center portion of the cooling tube 241 in a cross-sectional view perpendicular to the extension direction of the cooling tube 241, and four adjacent tube fins 242 may be formed in a spiral shape as a whole.

In addition, in the second embodiment, the substrate 2 is disposed in a vertical posture to extend in the up-down direction, but the present invention is not limited thereto. The substrate 2 may be disposed in a horizontal posture to extend in the horizontal direction.

In addition, in the second embodiment, the cooling device 210 is operated in a state where the first refrigerant R1 in the storage tank 220 is in a gas-liquid two-phase state, but the present invention is not limited thereto. The cooling device 210 may be operated in a stare where the first refrigerant R1 in the storage tank 220 is in a liquid single-phase state.

### First Modification Example of Second Embodiment

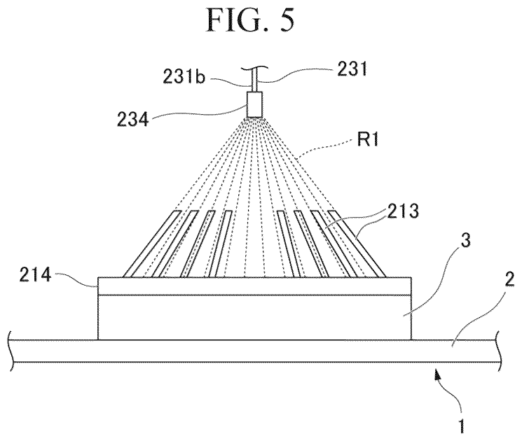

Next, a first modification example of the second embodiment will be described with reference to FIG. 5.

As shown in FIG. 5, in the present modification example, the fins 213 are provided on the surface of the heat generating body 3 facing the spray unit 234. A heat transfer plate 214 is provided between the fins 213 and the heat generating body 3. The heat transfer plate 214 is thermally connected to the heat generating body 3. In addition, the functionality may be improved by sealing ammonia or an alcohol-based liquid in the entire region inside the heat transfer plate 214. The fins 213 are formed in a pin shape extending from the heat transfer plate 214 toward the spray unit 234. The fins 213 are thermally connected to the heat generating body 3 via the heat transfer plate 214.

The refrigerant supply unit 230 causes the first refrigerant R1 to collide with the fins 213. The refrigerant supply unit 230 sprays the first refrigerant R1 toward the heat generating body 3 in a so-called spray shape to spread radially approaching the heat generating body 3. The fins 213 extend along the spray direction of the first refrigerant R1.

In the present modification example, the cooling device 210 includes the fins 213 thermally connected to the heat generating body 3. The refrigerant supply unit 230 causes the first refrigerant R1 to collide with the fins 213.

As a result, the contact area between the heat generating body 3 and the first refrigerant R1 is increased. That is, the heat transfer area between the heat generating body 3 and the first refrigerant R1 is increased. Therefore, the first refrigerant R1 can perform more favorable heat exchange with the heat generating body 3. Therefore, the cooling efficiency of the cooling device 210 can be further improved.

In addition, in the present modification example, the refrigerant supply unit 230 sprays the first refrigerant R1 to spread radially approaching the heat generating body 3, and the fins 213 extend along the spray direction of the first refrigerant R1.

As a result, the cooling device 210 can suppress the scattering of the first refrigerant R1 sprayed onto the fins 213. Therefore, the cooling efficiency of the cooling device 210 can be further improved.

### Second Modification Example of Second Embodiment

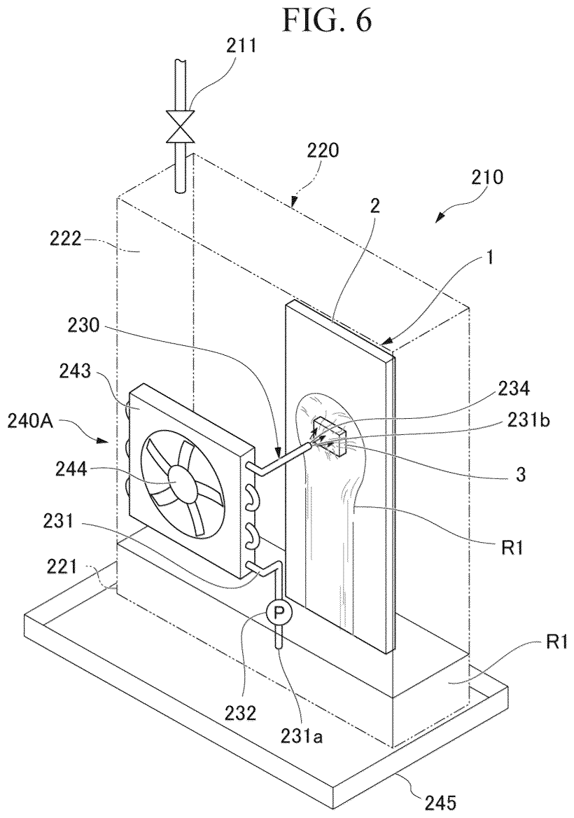

Next, a second modification example of the second embodiment will be described with reference to FIG. 6.

As shown in FIG. 6, in the present modification example, a part of the circulation pipe 231 of the refrigerant supply unit 230 between one end 23 la and the other end 231b is drawn out to the outside of the storage tank 220. The refrigerant supply unit 230 is provided in the circulation pipe 231 drawn out to the outside.

The refrigerant cooling unit 240A is disposed outside the storage tank 220. The refrigerant cooling unit 240A includes a casing 243, a heat exchanger (not shown), and a propeller fan 244. The casing 243 is formed in a rectangular plate shape. The casing 243 is attached to a side wall of the storage tank 220. The heat exchanger of the refrigerant cooling unit 240A is disposed in the casing 243. The first refrigerant R1 drawn from the storage tank 220 is supplied to the heat exchanger. The propeller fan 244 blows air to the heat exchanger in the casing 243. As a result, the air supplied by the propeller fan 244 and the first refrigerant R1 are subjected to heat exchange, and the first refrigerant R1 is cooled.

In addition, the cooling device 210 includes a pan 245 below the storage tank 220. The pan 245 is a container having a box shape that extends in the horizontal direction and has a rectangular parallelepiped shape. The pan 245 is open upward. The pan 245 prevents the first refrigerant R1 from leaking.

In addition, the configuration in which the refrigerant cooling unit 240A is provided outside the storage tank 220 as in the present modification example may be applied to the first embodiment.

Hitherto, each embodiment of the present disclosure has been described in detail with reference to the drawings. However, a specific configuration is not limited to the embodiment, and the present disclosure also includes a design change within the scope not departing from the concept of the present disclosure.

### Supplementary Notes

The cooling device 10 or 210 described in each embodiment is understood, for example, as follows.
(1) A cooling device 10 or 210 according to a first aspect includes: a storage tank 20 or 220 configured to store a liquid-phase first refrigerant R1 below a heat generating body 3; a refrigerant supply unit 30 or 230 configured to pump up the first refrigerant R1 in the storage tank 20 or 220 and supply the first refrigerant R1 to the heat generating body 3; and a refrigerant cooling unit 40, 240, or 240A configured to cool the first refrigerant R1 by supplying a second refrigerant R2 having a lower temperature than the first refrigerant R1 and performing heat exchange between the first refrigerant R1 and the second refrigerant R2, and the storage tank 20 or 220 recovers the first refrigerant R1 supplied to the heat generating body 3.

As a result, the first refrigerant R1 supplied to the heat generating body 3 moves downward due to its own weight and returns to the storage tank 20 or 220. The first refrigerant R1 returned to the storage tank 20 or 220 is again supplied to the heat generating body 3 by the refrigerant supply unit 30 or 230. Therefore, the storage tank 20 or 220 may temporarily store the first refrigerant R1 before the first refrigerant R1 is supplied to the heat generating body 3. Therefore, the cooling device 10 or 210 do not need to fill the storage tank 20 or 220 with the first refrigerant R1 to the extent in which the heat generating body 3 can be immersed in the storage tank 20 or 220.
(2) In the cooling device 10 according to a second aspect, which is the cooling device 10 of (1), the heat generating body 3 may be provided on a substrate 2 that extends in an up-down direction above the storage tank 20, and the refrigerant supply unit 30 may cause the first refrigerant R1 to flow downward on the substrate 2 to form a liquid film M of the first refrigerant R1 in a region including the heat generating body 3 on the substrate 2.

As a result, the cooling device 10 can cause the first refrigerant R1 to flow at a constant speed.
(3) In the cooling device 10 according to a third aspect, which is the cooling device 10 of (2), the refrigerant cooling unit 40 may supply the second refrigerant R2 to a liquid film M of the first refrigerant R1 formed on the substrate 2.

As a result, the refrigerant cooling unit 40 can directly cool the liquid film M of the first refrigerant R1.
(4) In the cooling device 10 according to a fourth aspect, which is the cooling device 10 of (3), the refrigerant cooling unit 40 may supply the second refrigerant R2 to a region on the substrate 2 where a heat generation density is high.

As a result, the cooling device 10 can cool a region having a high heat generation density on the substrate 2 including the heat generating body 3 with both the first refrigerant R1 and the second refrigerant R2.
(5) In the cooling device 10 according to a fifth aspect, which is the cooling device 10 of any one of (2) to (4), a part of the first refrigerant R1 may evaporate on the substrate 2.

Accordingly, the cooling device 10 can cool the region on the substrate 2 including the heat generating body 3 by using the evaporation latent heat in a case where the first refrigerant R1 evaporates.
(6) In the cooling device 10 according to a sixth aspect, which is the cooling device 10 of any one of (2) to (5), fins 11 may further be provided in a region on the substrate 2 where the liquid film M of the first refrigerant R1 is formed.

Accordingly, the cooling device 10 can control the thickness of the liquid film M of the first refrigerant R1 by passing the fins 11 through the liquid film M of the first refrigerant R1. In addition, the contact area between the substrate 2 and the first refrigerant R1 is increased by the fins 11. That is, the heat transfer area between the substrate 2 and the first refrigerant R1 is increased.
(7) In the cooling device 210 according to a seventh aspect, which is the cooling device 210 of (1), the refrigerant supply unit 30 or 230 may spray the first refrigerant R1 toward the heat generating body 3.

As a result, the cooling device 210 can cause the first refrigerant R1 to collide with the heat generating body 3.
(8) In the cooling device 210 according to an eighth aspect, which is the cooling device 210 of (7), fins 213 configured to be thermally connected to the heat generating body 3 may further be provided, and the refrigerant supply unit 230 may cause the first refrigerant R1 to collide with the fins 213.

As a result, the contact area between the hear generating body 3 and the first refrigerant R1 is increased. That is, the heat transfer area between the heat generating body 3 and the first refrigerant R1 is increased.
(9) In the cooling device 210 according to a ninth aspect, which is the cooling device 210 of (8), the refrigerant supply unit 230 may spray the first refrigerant R1 to spread radially approaching the heat generating body 3, and the fins 213 may extend along a spray direction of the first refrigerant R.I.

As a result, the cooling device 210 can suppress the scattering of the first refrigerant R1 sprayed onto the fins 213.
(10) In the cooling device 210 according to a tenth aspect, which is the cooling device 210 of any one of (1) to (9), a fan 212 may further be provided in the storage tank 220, the storage tank 220 may accommodate the heat generating body 3 inside and store the gas-phase first refrigerant R1 inside, and the fan 212 may circulate the gas-phase first refrigerant R1 in the storage tank 220.

As a result, the fan 212 can circulate the gas-phase first refrigerant R1 inside the storage tank 220. Therefore, the cooling device 210 can transfer the high-temperature heat accumulated above the storage tank 20 or 220 to the liquid-phase first refrigerant R1 stored in the bottom portion 221 of the storage tank 220.

### INDUSTRIAL APPLICABILITY

According to the cooling device of the present disclosure, the amount of refrigerant used can be reduced.

### REFERENCE SIGNS LIST

1 Server
2 Substrate
3 Heat generating body
10 Cooling device
11 Fin
20 Storage tank
21 Bottom portion
30 Refrigerant supply unit
31 Circulation pipe
31a One end
31b Other end
32 Pump
33 Header pipe
34 Supply hole
40 Refrigerant cooling unit
41 Cooling fan
210 Cooling device
220 Storage tank
221 Bottom portion
222 Upper portion
211 Relief valve
212 Fan
213 Fin
214 Heat transfer plate
230 Refrigerant supply unit
231 Circulation pipe
231a One end
231b Other end
232 Pump
233 Filter
234 Spray unit
240 Refrigerant cooling unit
240A Refrigerant cooling unit
241 Cooling tube
242 Tube fin
243 Casing
244 Propeller fan
245 Pan
M Liquid film
R1 First refrigerant
R2 Second refrigerant
R21 Air

1. A cooling device comprising:
a storage tank configured to store a liquid-phase first refrigerant below a heat generating body;
a refrigerant supply unit configured to pump up the first refrigerant in the storage tank and supply the first refrigerant to the heat generating body; and
a refrigerant cooling unit configured to cool the first refrigerant by supplying a second refrigerant having a lower temperature than the first refrigerant and performing heat exchange between the first refrigerant and the second refrigerant, wherein
the storage tank recovers the first refrigerant supplied to the heat generating body,
the heat generating body is provided on a substrate that extends in an up-down direction above the storage tank, and
the refrigerant supply unit supplies the first refrigerant from an upper edge of the substrate and causes the first refrigerant to flow toward a lower edge, and forms a liquid film of the first refrigerant in a region including the heat generating body on the substrate.

2. (canceled)

3. The cooling device according to claim 1, wherein
the refrigerant cooling unit supplies the second refrigerant to the liquid film of the first refrigerant formed on the substrate.

4. The cooling device according to claim 3, wherein
the refrigerant cooling unit supplies the second refrigerant to a region on the substrate where a heat generation density is high.

5. The cooling device according to claim 1, wherein
a part of the first refrigerant evaporates on the substrate.

6. The cooling device according to claim 1, further comprising:
fins in a region on the substrate where the liquid film of the first refrigerant is formed.

7. A cooling device comprising:
a storage tank configured to store a liquid-phase first refrigerant below a heat generating body;
a refrigerant supply unit configured to pump up the first refrigerant in the storage tank and supply the first refrigerant to the heat generating body; and
a refrigerant cooling unit configured to cool the first refrigerant by supplying a second refrigerant having a lower temperature than the first refrigerant and performing heat exchange between the first refrigerant and the second refrigerant, wherein
the storage tank recovers the first refrigerant supplied to the heat generating body, and
the refrigerant supply unit faces the heat generating body and sprays the first refrigerant toward the heat generating body.

8. The cooling device according to claim 7, further comprising:
fins configured to be thermally connected to the heat generating body, wherein
the refrigerant supply unit causes the first refrigerant to collide with the fins.

9. The cooling device according to claim 8, wherein
the refrigerant supply unit sprays the first refrigerant to spread radially approaching the heat generating body, and
the fins extend along a spray direction of the first refrigerant.

10. The cooling device according to claim 1, further comprising:
a fan in the storage tank, wherein
the storage tank accommodates the heat generating body inside and stores a gas-phase first refrigerant inside, and
the fan circulates the gas-phase first refrigerant in the storage tank.
